(19) United States
(12) Patent Application Publication
(10) Pub. No.: US 2009/0044851 A1
(43) Pub. Date: Feb. 19, 2009

(54) SOLAR POWER SYSTEM

(76) Inventor: Devon G. Crowe, Tucson, AZ (US)

Correspondence Address: Jonathan A. Platt;Renner, Otto, Boisselle & Sklar, LLP, 19th Floor, 1621 Euclid Ave., Cleveland, OH, 44115, US

(21) Appl. No.: 11/837,699

(22) Filed: Aug. 13, 2007

(51) Int. Cl. H01L 31/052; H01L 31/04

(52) U.S. Cl. 136/246; 136/259

(57) ABSTRACT

A solar collector includes one or more diffractive optical elements that concentrate light in two dimensions. The optical elements may be flat inexpensive plastic gratings or holograms, The elements provide an inexpensive way to concentrate sunlight or other radiation, for example directing the radiation to a collector such as one or more photovoltaic devices. The radiation may be binned in different wavelengths, and directed to different collector devices. The optical elements may have diffractive gratings on their surfaces, or alternatively may have internal gratings, for example provided by internal variations in index of refraction. Thus the optical elements may be volume phase gratings or suitable such diffractive elements. Volume holograms offer reduced solar tracking requirements compared to surface gratings.

### BACKGROUND OF THE INVENTION

1. Technical Field of the Invention

This invention relates generally to solar power systems, and optical elements for concentrating sunlight in such systems.

2. Description of the Related Art

Solar power systems have often used parabolic mirrors to concentrate sunlight to photovoltaic cells and thermal engines. Such mirrors are expensive and difficult to manufacture.

A one-dimensional focusing grating has been proposed in the past for use in focusing sunlight in a spectrally dispersed band. Such gratings are limited in usefulness due to the limited concentration of sunlight, and due to limited ability to allocate spectrally dispersed energy bins. Accordingly parabolic mirrors have been the usual device to accomplish solar concentration.

From the foregoing it will be appreciated that improvements are possible in the field of solar power systems.

### SUMMARY OF THE INVENTION

According to an aspect of the invention, a solar power system includes a flat diffractive solar concentration element that concentrates incoming light in two dimensions.

According to another aspect of the invention, a solar power system includes a solar concentrator that includes two or more concentration elements in series.

According to still another aspect of the invention, a solar power system includes an optical element that has internal variations in index of refraction, such as a volume hologram, used to diffract and concentrate incoming light.

According to yet another aspect of the invention, a solar power system includes a pair of optical elements for concentrating light, and a solar tracking motor or other suitable means for moving one of the elements relative to the other of the elements.

According to a further aspect of the invention, a solar power system includes a motor or other suitable means for moving one or more photovoltaic elements relative to a solar concentrator.

According to a still further aspect of the invention, a solar power system includes a solar concentrator that concentrates incoming sunlight. The solar concentrator includes at least one diffractive optical element that concentrates light in two dimensions. The solar power system may include one or more photovoltaic elements that receive concentrated light from the solar concentrator, and that convert the concentrated light into electrical energy.

According to another aspect of the invention, a method of producing electricity includes the steps of: concentrating sunlight in a solar concentrator, wherein the solar concentrator includes one or more diffractive elements that concentrate the sunlight in two dimensions; and passing the concentrated light to one or more photovoltaic elements.

According to yet another aspect of the invention, a method of concentrating energy includes passing the energy to a diffraction element that concentrates the energy in at least two dimensions.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

In the annexed drawings, which are not necessarily to scale:

FIG. 1 is a schematic diagram of a solar power system in accordance with one embodiment of the present invention;

FIG. 2 is a schematic diagram of a second embodiment solar power system in accordance with the present invention;

FIG. 3 is a schematic diagram of a third embodiment solar power system in accordance with the present invention;

FIG. 4 is a schematic diagram of a fourth embodiment solar power system in accordance with the present invention;

FIG. 5 is an oblique view of an optical element in accordance with an embodiment of the invention;

FIG. 6 is a schematic diagram of an energy concentration system in accordance with an embodiment of the invention.

### DETAILED DESCRIPTION

A solar collector includes one or more diffractive optical elements that concentrate light in two dimensions. The optical elements may be flat inexpensive plastic gratings, for example made out of epoxy. The elements provide an inexpensive way to concentrate sunlight or other radiation, for example directing the radiation to a collector such as one or more photovoltaic devices. The radiation may be binned in different wavelengths, and directed to different collector devices. The optical elements may have diffractive gratings on their surfaces, or alternatively may have internal gratings, for example provided by internal variations in index of refraction. Thus the optical elements may be volume phase gratings or suitable such diffractive elements.

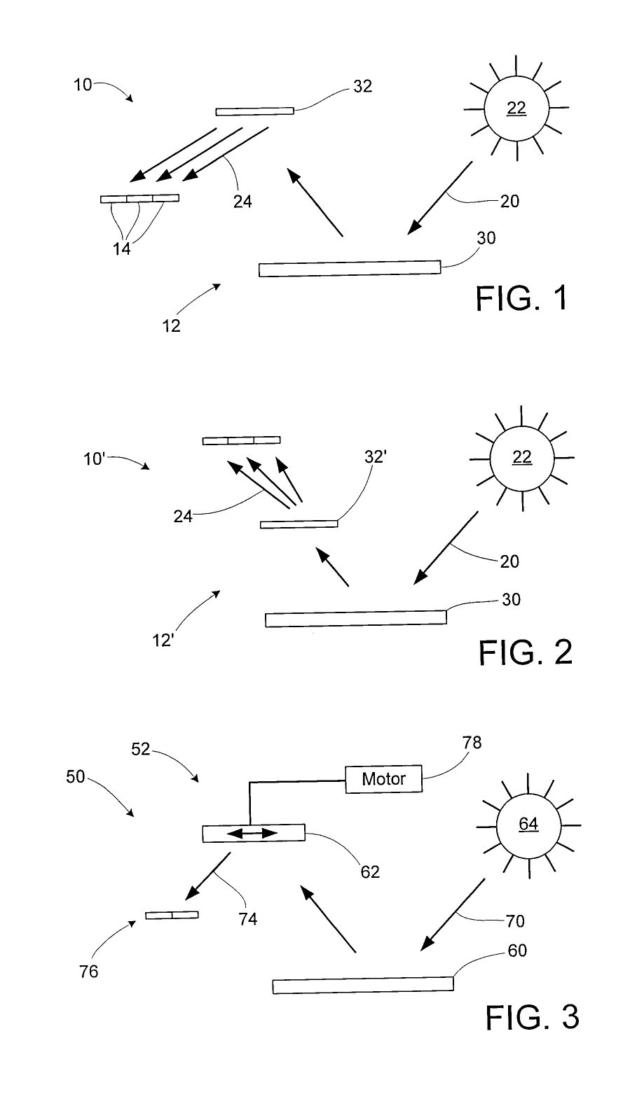

FIG. 1 shows a solar power system 10 that includes a solar concentrator 12 and photovoltaic elements 14. The solar concentrator 12 receives incoming sunlight 20 from the sun 22, focuses it, and passes along concentrated light 24 to the photovoltaic elements 14. The solar concentrator 12 includes a first diffractive optical element 30 and a second diffractive optical element 32. The diffractive elements 30 and 32 sequentially concentrate the sunlight 20. Each of the diffractive optical elements 30 and 32 may be used to concentrate incident light in two dimensions, for example in two orthogonal directions along the surfaces of the optical elements 30 and 32. The diffraction characteristics of the optical elements 30 and 32 have chirp in both directions, enabling concentration of the incident light in both directions. The concentration in each of the optical elements 30 and 32 in each of the directions may be a ratio of about 10 to 1. The overall concentration in each of the elements may be about 100 to 1, and the total concentration of the solar concentration 12 may be about 10,000 to 1.

As illustrated in FIG. 1, the optical elements 30 and 32 may be reflective diffractive elements. The optical elements 30 and 32 may be substantially flat elements, for example being slabs of stamped or molded plastic. The optical elements 30 and 32 may have surface features that provide diffraction for the elements 30 and 32. Alternatively the diffraction for the optical elements 30 and 32 may be provided by internal features, such as by internal variations in index of refraction in the optical elements 30 and 32. Further details on many of these possibilities are provided below.

The photovoltaic elements 14 may include different types of photovoltaic elements that preferentially convert different wavelengths of light into electrical energy. The various photovoltaic elements 14 may be located such that they receive different wavelengths of light diffracted by the solar collector, the wavelengths that the individual photovoltaic elements preferentially convert to electrical energy.

Many alternatives are possible. Alternatively there may be only one photovoltaic element, or there may be multiple photovoltaic elements of the same type, or multiple photovoltaic elements that cover different spectral regions in order to increase the solar conversion efficiency from photons to electric current. There may be more or fewer diffractive optical elements than in the illustrated embodiment.

FIG. 2 shows an alternative configuration solar power system 10′, with a solar concentrator 12′ having a second optical element 32′ that is a transmissive diffractive element. In other respects the solar power system 10′ may be similar to the solar power system 10 of FIG. 1. The diffractive optical elements of solar collectors may be reflective, transmissive, or a combination of both. Other elements shown in FIG. 2, such as the sunlight 20, the sun 22, the concentrated light 24, and the first optical element 30, may be similar to those shown in FIG. 1.

Turning now to FIG. 3, a solar power system 50 has a solar concentrator 52 that includes means for moving one of its diffractive optical elements 62 relative to another diffractive optical element 60. As the sun 64 changes position in the sky, the incoming sunlight 70 changes its angle of incidence on the first diffractive optical element 60. By moving the second optical element 62 relative to the first optical element 60, a similar location for the concentrated light 74, such as a location incident on one or more photovoltaic elements 76, may be maintained. A motor 78 may be used to move the second optical element 62 relative to the first optical element 60. It will be appreciated that a wide variety of suitable mechanisms and types of movement may be used for accomplishing relative movement between the optical elements 60 and 62.

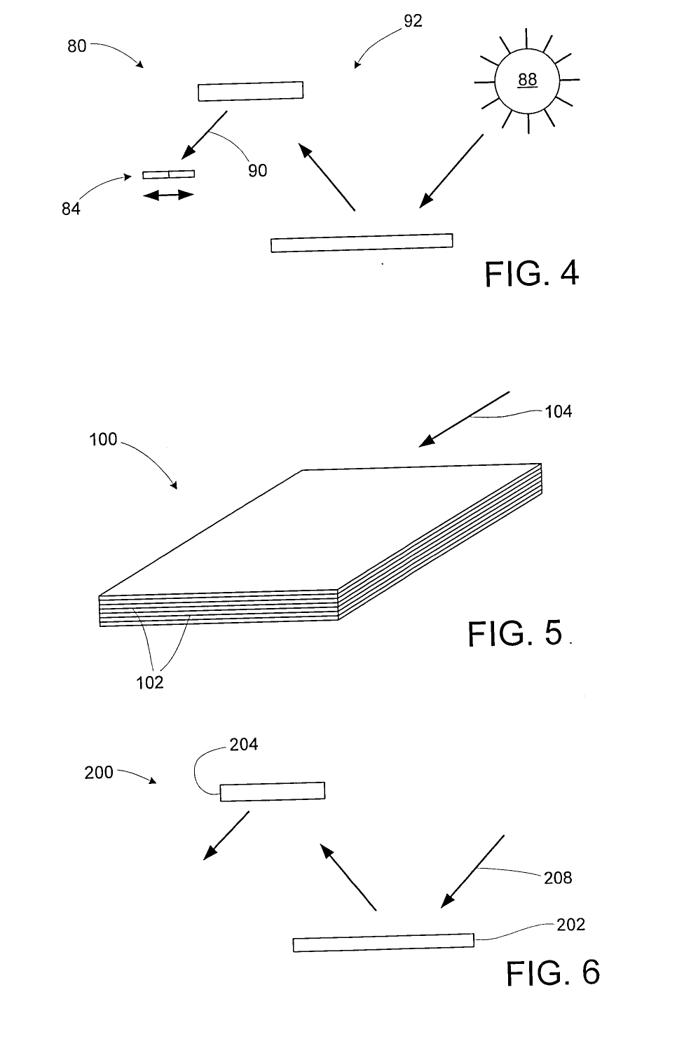

FIG. 4 shows an alternative approach to compensating for movement of the sun, in which a solar power system 80 has movable photovoltaic elements 84. As incoming sunlight 86 changes its angle due to movement of the sun 88, the location of outgoing light 90 from a solar concentrator 92 changes. Movement of the photovoltaic elements 84 can be used to compensate for this change in location of the outgoing light 90. A motor 92 or other suitable mechanisms may be used to move the photovoltaic elements 84. The photovoltaic elements 84 may be moved individually or as a unit.

Another alternative approach to compensating for sun movement is shown in FIG. 5, embodied as a diffractive optical element 100. The optical element 100 has multiple internal layers 102 with different index of refraction profiles within the layers 102. As solar energy 104 changes its angle of incidence with the optical element 100 (due to the earth's rotation creating apparent solar motion), the direction of the sun's rays change to match the acceptance angle of a different volume holographic element within the volume hologram. A large number of holograms can simultaneously co-exist within the volume of the holographic material. These holograms create a time history in which the solar image traces short arcs at the focus of the 2D grating concentrator. These arcs are more easily tracked than the entire diurnal motion across the sky.

The diffraction optical elements described above may have any of a wide variety of forms. The optical element may be in the form of a grating, such as a phase grating. The grating has a variation in spatial frequency (also known as “chirp”) in one or more directions, to concentrate incident light of multiple wavelengths in one or more desired directions. The grating may be for example a series of reflective strips that diffract and concentrate incoming light. Other alternative types of gratings include surface-relief shape grating patterns in the material of the optical elements, such as blazed gratings. The diffractive gratings may be fabricated as computer generated holograms, transmissive phase gratings, reflective gratings, or amplitude gratings. Gratings and holographic elements can be designed and fabricated to either affect the phase of the wavefront or the amplitude of wavefront, or to affect both the phase and the amplitude.

The diffractive optical elements may also involve gratings in the interior of the optical elements. Volume phase gratings and volume-phase holographic gratings are well-known types of internal phase gratings. The phase gratings or holograms modulate the index of refraction within the material, while amplitude devices affect the wavefront transmission or reflection as a function of spatial position. It is possible to fabricate these holographic elements using optical exposure on an optical bench, or to write the desired pattern either with a laser or lithographically to create a computer-generated hologram (CGH). The optical elements may have three-dimensional index of refraction variations. The volume phase grating is a generalization of sandwiching multiple planar holograms. Stacks of 2D holograms can be used to approximate a volume hologram, or to serve as multi-angle-of-acceptance independent devices.

As noted above, the 2D optical elements may be made of a suitable plastic, such as a molded, pressed, or stamped epoxy. A polyimide optical element may be manufactured using a suitable cylindrical master. Alternative materials may include suitable metamaterials and/or photonic crystals. The material of the optical elements may have positive and/or negative index of refraction. Photonic crystals are a generalization of surface diffraction gratings.

The optical elements may have any of a wide variety of overall sizes, from on the order of millimeters to on the order of kilometers. The size of the variations of gratings also may vary over a wide range, for example from half a wavelength of the light to be diffracted, to on the order of millimeters.

The optical element may also include addressable portions that may be individually altered, for example to change characteristics of the addressable portions to redirect light. An electronically addressable spatial light modulator (SLM) can be used to create a 2D addressable grating or CGH. Suitable electrodes may be selectively actuated to change light characteristics by selectively changing light polarization characteristics of parts of the optical element. A set of these SLMs can be stacked to form an addressable volume hologram. The volume hologram can be imbued with any of the characteristics listed here to include multi-angle diffraction and chirp wavelength compensation. The current economics of solar power generation, and the static nature of the optical task will often argue for inexpensive replicated CGH or gratings. As the cost of addressable volume CGH declines, a possible application is to track the sun and eliminate the need for motor drives of any kind.

The concept of using flat diffractive elements for concentrating energy may be extended beyond concentration of sunlight. This creates the ability to use low mass deployable gratings and CGH for applications such as large aperture imaging in space. FIG. 6 includes an energy concentration system 200 that includes flat diffractive elements 202 and 204 for concentrating incoming energy 208. The diffractive elements 202 and 204 may be similar in structure to the various optical elements described above. The energy concentration may be any of a wide variety of types of energy, including optical wavelengths, radio wavelengths, infrared and ultraviolet radiation, X-rays, and analogs exist for concentrating any wave phenomenon, such as acoustic energy.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. A solar power system comprising:
a solar concentrator that concentrates incoming sunlight; and
wherein the solar concentrator includes at least one diffractive optical element that concentrates light in two dimensions.

2. The system of claim 1, further comprising one or more photovoltaic elements that receive concentrated light from the solar concentrator, and that convert the concentrated light into electrical energy.

3. The system of claim 2,
wherein the one or more photovoltaic elements includes multiple photovoltaic elements that preferentially convert different wavelengths of light into electrical energy; and
wherein the solar concentrator directs different wavelengths of the incoming sunlight to different of the photovoltaic elements.

4. The system of claim 1, wherein the at least one diffractive element includes a reflective diffractive element.

5. The system of claim 1, wherein the at least one diffractive element includes a transmissive diffractive element.

6. The system of claim 1, wherein the at least one diffractive optical element includes two or more diffractive optical elements.

7. The system of claim 6, wherein one of the diffractive elements is movable relative to another of the diffractive elements to compensate for differences in direction of the incoming sunlight.

8. The system of claim 1, wherein the one or more photovoltaic elements are movable to compensate for differences in direction of the incoming sunlight.

9. The system of claim 1, wherein the at least one diffractive optical element includes a diffractive optical element with internal variations in index of refraction.

10. The system of claim 9, wherein the diffractive element with the internal variations in index of refraction includes multiple layers of index of refraction variation for differently diffracting different angles of incident light.

11. The system of claim 10, wherein the multiple layers of index of refraction variation provide substantially the same direction for the concentrated light over a range of incoming sunlight directions.

12. The system of claim 9, wherein the internal variations in index of refraction direct different wavelengths of incoming light in different directions.

13. The system of claim 9, wherein the diffractive optical element with the internal variations in index of refraction includes a volume-phase holographic grating.

14. The system of claim 1, wherein the at least one diffractive optical element includes a plastic diffractive optical element.

15. The system of claim 1, wherein the at least one diffractive optical element includes a substantially flat diffractive optical element.

16. A method of producing electricity, the method comprising:
concentrating sunlight in a solar concentrator, wherein the solar concentrator includes one or more diffractive elements that concentrate the sunlight in two dimensions; and
passing the concentrated light to one or more photovoltaic elements.

17. The method of claim 16, wherein the concentrating includes concentrating the sunlight using index of refraction differences within the one or more diffractive elements.

18. The method of claim 16, wherein the one or more diffractive elements are substantially flat.

19. The method of claim 16,
wherein the one or more photovoltaic elements includes multiple photovoltaic elements;
wherein the concentrating includes spatially separating different wavelengths of the sunlight; and
wherein the passing includes passing different wavelengths of the concentrated light to different of the photovoltaic elements.

20. A method of concentrating energy, the method comprising:
passing the energy to a diffraction element that concentrates the energy in at least two dimensions.
